(19) United States
(12) Patent Application Publication
(10) Pub. No.: US 2026/0096492 A1
(43) Pub. Date: Apr. 2, 2026

(54) PROCESSES FOR MANUFACTURING WAFER-ON-WAFER DEVICES, AND SYSTEMS INCORPORATING SUCH DEVICES

(71) Applicant: Advanced Micro Devices, Inc., Santa Clara, CA (US)

(72) Inventors: Chandra Sekhar Mandalapu, Lehi, UT (US); Deepak Vasant Kulkarni, Austin, TX (US); Sai Vadlamani, Austin, TX (US); Arsalan Alam, Austin, TX (US); Robert Grant Spurney, Austin, TX (US)

(73) Assignee: Advanced Micro Devices, Inc., Santa Clara, CA (US)

(21) Appl. No.: 19/342,383

(22) Filed: Sep. 26, 2025

Related U.S. Application Data
(60) Provisional application No. 63/701,122, filed on Sep. 30, 2024.

(51) Int. Cl. H10W 90/20

(52) U.S. Cl. CPC H10W 90/297

(57) ABSTRACT

Described herein are various embodiments of wafer-on-wafer manufacturing processes and devices that can be produced during or as a result of such processes. In a wafer-on-wafer process, two or more wafers including semiconductor, conductive, and/or insulating material with circuit components formed thereon can be bonded and diced to yield assemblies each including multiple dies. In some implementations, one die can include one or more integrated passive devices (e.g., deep trench capacitors) and one die can include power delivery circuitry, such as power regulation circuitry (e.g., voltage regulation circuitry).

### CROSS REFERENCE TO RELATED APPLICATION

This application claims the benefit of U.S. Provisional Application No. 63/701,122, filed Sep. 30, 2024, the entire disclosure of which is hereby incorporated by reference herein.

### BACKGROUND

Wafer-on-wafer (WoW) processes are advanced semiconductor manufacturing processes used to stack two or more wafers before dicing the stacked wafers into individual semiconductor chips. Some WoW processes involve thinning one or more of the wafers before stacking to reduce the thickness of the stacked chips.

Integrated circuit (IC) packages are assemblies that can mechanically support, protect, interconnect, and thermally manage one or more semiconductor dies while providing standardized electrical and mechanical interfaces to a printed circuit board or system-level substrate. IC packages can incorporate die attach materials, interposer or substrate layers with redistribution traces and vias, electrical interconnects such as wire bonds, micro-bumps, or solder balls, and encapsulation or lid structures to shield the dies from contamination and mechanical stress. IC packages often integrate thermal features such as heat spreaders, thermal vias, and/or conductive dielectrics, as well as power delivery networks and decoupling structures to facilitate reliable high-frequency operation. By consolidating these mechanical, electrical, and thermal functions into a single unit, IC packages can facilitate scalable assembly, testing, and deployment of complex multi-chip electronic systems.

### BRIEF DESCRIPTION OF THE DRAWINGS

The accompanying drawings illustrate a number of exemplary implementations and are a part of the specification. Together with the following description, these drawings demonstrate and explain various principles of the present disclosure.

FIG. 1A is a block diagram of an example device having a wafer-on-wafer assembly disposed in a cavity of a substrate.

FIG. 1B is a block diagram of an example of at least one die.

FIG. 1C is a block diagram of another example of at least one die.

FIGS. 1D and 1E are block diagrams of example devices that can be formed by wafer-on-wafer manufacturing processes, in accordance with some techniques described herein.

FIG. 1F is a block diagram of an example of a multi-chip package.

FIG. 2 is a flow diagram of an example wafer-on-wafer manufacturing process for stacking a first wafer comprising at least one capacitor and a second wafer comprising power delivery circuitry.

FIG. 3 is a flow diagram of another example wafer-on-wafer manufacturing process for producing a wafer-on-wafer assembly with a first wafer comprising at least one integrated passive device (IPD) and a second wafer comprising power delivery circuitry.

FIG. 4 is a cross-sectional view of an example of a die having one or more angled through-silicon vias, which can be formed in a manufacturing process in accordance with some techniques described herein.

FIG. 5 is a cross-sectional view of a conventional die having one or more angled through-silicon vias.

FIG. 6 is a flow diagram of an example wafer-on-wafer manufacturing process for producing a wafer-on-wafer assembly with a first die including an IPD and a second die including power delivery circuitry.

FIG. 7 is a flow diagram of an example process for assembling a device with a wafer-on-wafer assembly disposed in a cavity of a substrate of the device.

FIG. 8 is another flow diagram of the example assembly method of FIG. 7.

FIG. 9 is a block diagram of an example computer system in which at least one device has a cavity in a substrate with a wafer-on-wafer assembly disposed therein.

Throughout the drawings, identical reference characters and descriptions indicate similar, but not necessarily identical, elements. While the examples described herein are susceptible to various modifications and alternative forms, specific implementations have been shown by way of example in the drawings and will be described in detail herein. However, the example implementations described herein are not intended to be limited to the particular forms disclosed. Rather, the present disclosure covers all modifications, equivalents, and alternatives falling within the scope of the appended claims.

### DETAILED DESCRIPTION

Electronic devices, including stacked die devices, can be embedded in cavities formed within the substrates of integrated circuit packages. In a stacked die device, two or more vertically stacked semiconductor dies can be bonded together (e.g., using hybrid bonding or fusion bonding techniques) and electrically interconnected (e.g., using through-die vertical interconnects, micro-bumps, and/or redistribution layers routed into substrate traces), thereby enabling short, low-inductance signal paths between dies in the stack. Embedding such devices within the substrate plane of an IC package substrate helps maintain a planar package surface for standard heat spreader attachment and protects potentially fragile interconnects from mechanical stress and contamination. Thermal vias and dedicated thermal interface features can be integrated into the cavity walls and substrate to conduct heat away from the stacked dies to an external heat spreader or board-level thermal solution.

Embedding stacked die devices in substrate cavities generally increases interconnect density and improves signal integrity due to reduced interconnect length and controlled impedance routing through the substrate and redistribution layers. This architecture can enable smaller package footprints and lower package profiles compared to discrete stacked packages, facilitating denser system-level integration and shorter board-level routing that together reduce overall system latency and power consumption. In addition, the enclosed cavity can improve mechanical robustness and manufacturing yield by reducing stress on chip interfaces, while integrated thermal management structures and power-delivery routing can enhance heat dissipation and support higher performance operating points.

The present disclosure describes wafer-on-wafer manufacturing processes, devices (e.g., stacked die devices or “wafer-on-wafer assemblies”) that can be produced using such processes, and systems (e.g., integrated circuit packages) incorporating such devices. In some WoW manufacturing processes, a deep trench capacitor (DTC) wafer is attached to an integrated voltage regulator (IVR) wafer before thinning of the deep trench capacitor wafer, which can extend the cycle time of the manufacturing process. Waiting until after the DTC wafer is attached to the IVR wafer before forming one or more through silicon vias (TSV) in the DTC wafer can also extend the cycle time of the manufacturing process. In some examples, an exemplary WoW manufacturing process can include attaching the DTC wafer to a carrier wafer. In some examples, an exemplary WOW manufacturing process can include thinning the DTC wafer and/or forming one or more TSVs in the DTC wafer while the DTC wafer is attached to the carrier wafer. In some examples, the process can include attaching the DTC wafer to an IVR wafer after thinning the DTC wafer and/or forming the TSV(s) in the DTC wafer, thereby reducing the cycle time of the manufacturing process

In some implementations, the thickness of the WoW assembly preferably matches the depth of a substrate cavity in which the WoW assembly is disposed. In some examples, the WoW assembly includes a silicon die (e.g., a dummy silicon die) that increases the thickness of the WoW assembly to match the depth of the cavity. However, silicon dies can be poor conductors of heat (e.g., inadequate for conducting heat away from power delivery circuitry). In some examples, the WoW includes a thermal carrier die (instead of a silicon die) that increases the thickness of the WoW assembly to match the depth of the cavity. In some examples, the thermal carrier die can efficiently transfer heat away from the IVR die, as the thermal carrier die can be a good conductor of heat. In some examples, the thermal carrier die can also support increased capacitance density (relative to a silicon die), which can increase the total capacitance and/or capacitance density of the WoW assembly.

In a WoW process, two or more wafers including semiconductor, conductive, and/or insulating material with one or more electrical elements arranged within the wafer can be combined in a wafer-on-wafer manufacturing process and diced to yield (as an intermediate or final result of a manufacturing process) devices (WoW assemblies) each comprising multiple dies. In some implementations of this technique, one die can include one or more capacitors and one die can comprise power delivery circuitry, such as power regulation circuitry (e.g., voltage regulation circuitry). In some implementations described below, one or more conductive structures (e.g., metal layers, vias, or other structures) can be formed on one side of a wafer including at least one capacitor (e.g., at least one deep trench capacitor), such as when the wafer including the capacitor(s) is disposed on a temporary carrier wafer that is used for support during some stages of a manufacturing process before being eliminated during a subsequent stage. Following forming of the conductive structures on the first side of the capacitor wafer, one or more conductive structures can be formed on a second, opposite side of the capacitor wafer. In some such examples, the conductive structures can be formed on the second, opposite side following arrangement of a second temporary carrier wafer on the conductive structures of the first side and removal of the first carrier wafer. Subsequent to the forming of the conductive structures on the second side (such that, in this example, conductive structures have been formed on both sides of the wafer that includes the capacitor(s)), the capacitor wafer with the conductive structures and disposed on a carrier wafer can be set aside and stored before manufacturing continues, or the manufacturing can continue. Subsequently, another wafer having power delivery circuitry (e.g., voltage regulation circuitry, such as an integrated voltage regulator) can be combined with the capacitor wafer, such as by being bonded to the side of the capacitor wafer where the second conductive structures were formed. In some implementations, the remaining carrier wafer can be removed, the wafers can be diced, and the individual WoW assemblies can be packaged.

In some examples, the device can include one or more integrated passive devices (IPDs), such as deep trench capacitors (DTC), and an integrated voltage regulator (IVR) in a vertically stacked configuration. In certain examples, the IPD dies can be hybrid bonded to the IVR dic, which can deliver power to the IPDs and/or downstream logic devices (e.g., logic die).

The thinning of wafers during a WoW process can involve multiple, time-consuming process steps, and can lead to other process steps being delayed until the wafer-stacking step has been completed. For example, the cycle time of the wafer-on-wafer process can be extended when one or more manufacturing process steps are not performed on either wafer until the wafers are bonded. Such process steps can include thinning the wafers or steps performed after thinning the wafers, because individual thinned wafers alone can be too delicate for the subsequent process steps

In 3D stacking of silicon wafers, vertically stacked silicon wafers of devices can be electrically connected to one another in various ways to allow flow of electric current. For example, through-silicon vias (TSVs) provide a vertical electrical connection (via) that passes completely or partially through a wafer or die that is entirely or partially made of silicon, though through vias can be formed in other semiconductor materials as well. TSVs are high-performance interconnect techniques used as an alternative to wire-bond and flip devices to create 3D packages and 3D integrated circuits. Compared to alternatives such as package-on-package, the interconnect and device density is substantially higher, and the length of the connections becomes shorter. TSVs allow designers to increase performance and reduce power consumption significantly compared to indirect connection of devices.

TSVs can be used with various types of attachment techniques (e.g., microbumps, hybrid bonding, etc.) between wafers. Microbumps (e.g., solder balls), for example, can be used to connect TSVs of two wafers. Also, hybrid bonding can connect wafers using tiny copper-to-copper connections, as opposed to bumps. Hybrid bonds can yield a finer pitch (e.g., less than ten micrometers) compared to a pitch (e.g., greater than ten micrometers) achieved using microbumps. This smaller pitch can achieve further miniaturization of a semiconductor device and enable performance that is close to that of a monolithic wafer. Compared to TSVs with microbumps, TSVs with hybrid bonding can enable further increase in performance and reduce power consumption.

While some examples are given herein of the processes used in connection with a wafer comprising one or more deep trench capacitors and a wafer comprising one or more integrated voltage regulators, it should be appreciated that embodiments are not so limited. As explained in greater detail below, some implementations of some techniques described herein can provide a device including a first wafer, a second wafer, and a third wafer. In some examples, the second wafer can be conductively coupled to the first wafer with a through-silicon via, and the third wafer can refer to a temporary carrier wafer, which can be mounted on the second wafer opposite the first wafer. Additional components and/or temporary carrier wafers can be mounted on the first wafer and/or the second wafer, and the wafers can be diced to form wafer-on-wafer assemblies. In some implementations, a device (WoW assembly) produced by a wafer-on-wafer process can include a first die, where the first die can include at least one capacitor, a second die, where the second die can include power delivery circuitry, and a third die, where the third die can be a carrier die (e.g., thermal carrier die). In certain implementations, the second die can be electrically connected to the first die through a coupling associated with at least one TSV. In certain embodiments, the third die can support the first die during formation of the at least one conductive layer and/or the at least one TSV.

In some aspects, the techniques described herein relate to a device including: an assembly including a first die including a first integrated passive device (IPD), at least one through-silicon via (TSV) extending through the first die from a first surface of the first die to a second surface of the first die, and a second die including power delivery circuitry or a second IPD, wherein a surface of the second die is bonded to the first surface of the first die.

In some aspects, the techniques described herein relate to a device, further including a substrate having a cavity formed therein, wherein the assembly is disposed in the cavity.

In some aspects, the techniques described herein relate to a device, wherein the second die includes the power delivery circuitry, and the assembly further includes a third die including the second IPD, the third die being bonded to a second surface of the first dic.

In some aspects, the techniques described herein relate to a device, wherein the third die is fusion bonded to the second surface of the first die.

In some aspects, the techniques described herein relate to a device, wherein the first IPD includes a first deep trench capacitor, the second die includes the second IPD, and the second IPD includes a second deep trench capacitor.

In some aspects, the techniques described herein relate to a device, wherein the first die is fusion bonded to the second die.

In some aspects, the techniques described herein relate to a device, wherein the first IPD includes a first deep trench capacitor, the second IPD includes a second deep trench capacitor, and the power delivery circuitry includes an integrated voltage regulator.

In some aspects, the techniques described herein relate to a device, wherein the first die is fusion bonded to the third die, and the first die is fusion bonded to the second die.

In some aspects, the techniques described herein relate to a device, wherein the first IPD includes a deep trench capacitor, the second die includes the power delivery circuitry, and the power delivery circuitry includes an integrated voltage regulator.

In some aspects, the techniques described herein relate to a device, wherein the first surface of the first die is hybrid bonded to the second die, and the first die further includes a conductive layer formed on a second surface opposite the first surface.

In some aspects, the techniques described herein relate to a device, wherein a thickness of the assembly matches a thickness of the substrate having the cavity formed therein.

In some aspects, the techniques described herein relate to a device, wherein the thickness of the substrate is between 700 micrometers and 900 micrometers.

In some aspects, the techniques described herein relate to a device, wherein the first die or the second die includes a thermal carrier die.

In some aspects, the techniques described herein relate to a device, wherein the at least one TSV includes a middle configuration with an angular profile.

In some aspects, the techniques described herein relate to a method including: while a first wafer including a die including at least one integrated passive device (IPD) is disposed on a first carrier wafer, thinning the first wafer, forming one or more through-silicon vias (TSVs) through the die of the thinned first wafer, and forming at least one conductive layer on a first surface of the thinned first wafer; attaching a second carrier wafer to the at least one conductive layer, the second carrier wafer and the first wafer being positioned on opposite sides of the at least one conductive layer; and removing the first carrier wafer from a second surface of the first wafer.

In some aspects, the techniques described herein relate to a method, further including bonding a second wafer including a die including at least one power delivery circuit to the second surface of the first wafer.

In some aspects, the techniques described herein relate to a method, further including removing the second carrier wafer bonded to the at least one conductive layer.

In some aspects, the techniques described herein relate to a method including: forming a cavity within a substrate of an integrated circuit, placing a wafer-on-wafer assembly within the cavity of the substrate, wherein the wafer-on-wafer assembly includes a first die having a first integrated passive device (IPD) formed thereon and a second die having a second integrated passive device (IPD) formed thereon; filing the cavity with a material including resin after placing the wafer-on-wafer assembly within the cavity; and laminating a first surface and a second surface of the integrated circuit.

In some aspects, the techniques described herein relate to a method, wherein wafer-on-wafer assembly further includes a third die having power delivery circuitry formed thereon.

In some aspects, the techniques described herein relate to a method, wherein a thickness of the wafer-on-wafer assembly matches a thickness of the cavity within the substrate.

In some aspects, the techniques described herein relate to a multi-chip package including: a substrate, wherein a cavity is formed within the substrate; a wafer-on-wafer assembly disposed within the cavity of the substrate, wherein the wafer-on-wafer assembly includes a first die including a first integrated passive device (IPD) and a second die including power delivery circuitry or a second integrated passive device (IPD); and an integrated circuit communicatively coupled to the wafer-on-wafer assembly via one or more interconnects.

In some aspects, the techniques described herein relate to a multi-chip package, wherein the integrated circuit is a first integrated circuit, and wherein the substrate is a core substrate of a printed circuit board or a substrate of a second integrated circuit.

In some aspects, the techniques described herein relate to a multi-chip package, wherein at least one of the one or more interconnects is routed through the substrate.

In some aspects, the techniques described herein relate to a multi-chip package, wherein the first integrated circuit is disposed on the substrate.

In some aspects, the techniques described herein relate to a multi-chip package, further including an interposer disposed over the substrate, wherein at least one of the one or more interconnects is routed through the interposer.

In some aspects, the techniques described herein relate to a multi-chip package, wherein the first integrated circuit is disposed on the interposer.

In some aspects, the techniques described herein relate to a multi-chip package, wherein the wafer-on-wafer assembly further includes at least one through-silicon via (TSV) extending through the first die from a first surface of the first die to a second surface of the first die.

In some aspects, the techniques described herein relate to a multi-chip package, wherein a surface of the second die is bonded to the first surface of the first die.

In some aspects, the techniques described herein relate to a multi-chip package, wherein the second die includes the power delivery circuitry, and the wafer-on-wafer assembly further includes a third die including the second IPD.

In some aspects, the techniques described herein relate to a multi-chip package, wherein a material including resin is disposed within the cavity.

Features from any of the implementations described herein can be used in combination with one another in accordance with the general principles described herein. These and other implementations, features, and advantages will be more fully understood upon reading the following detailed description in conjunction with the accompanying drawings and claims.

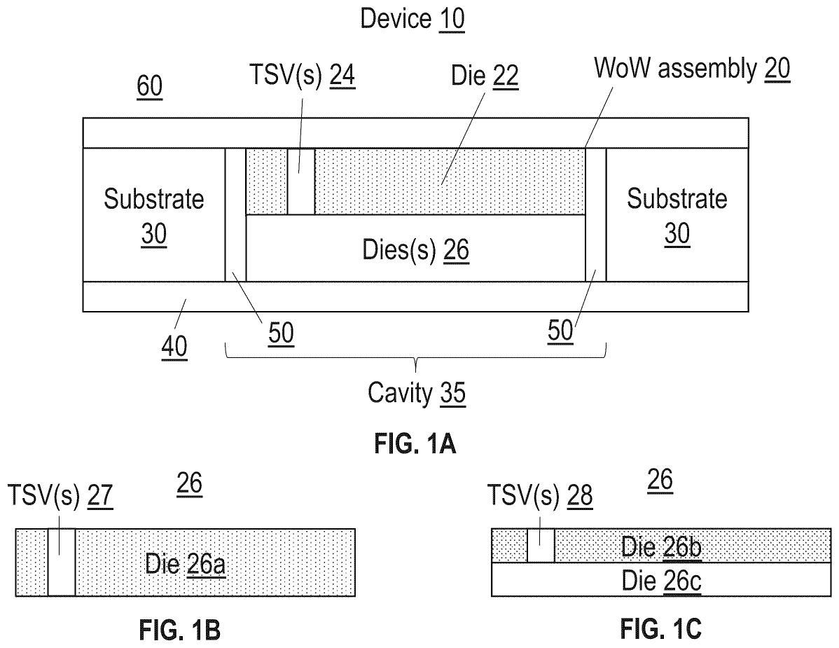

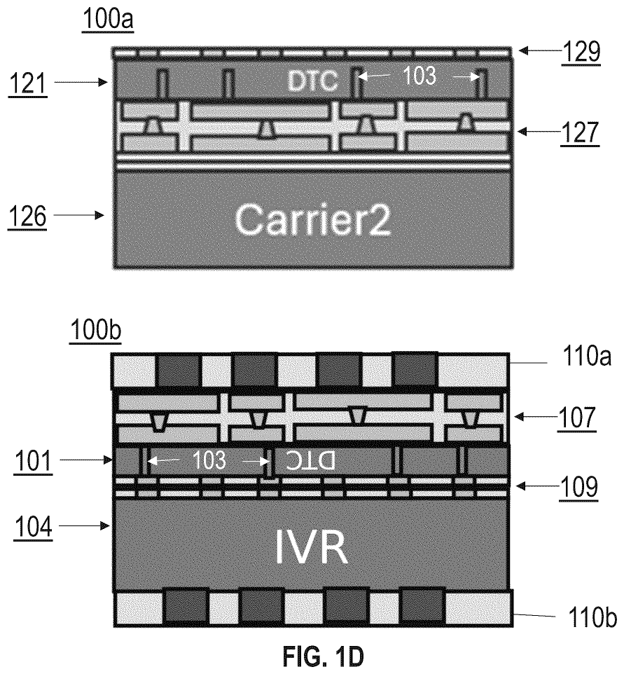

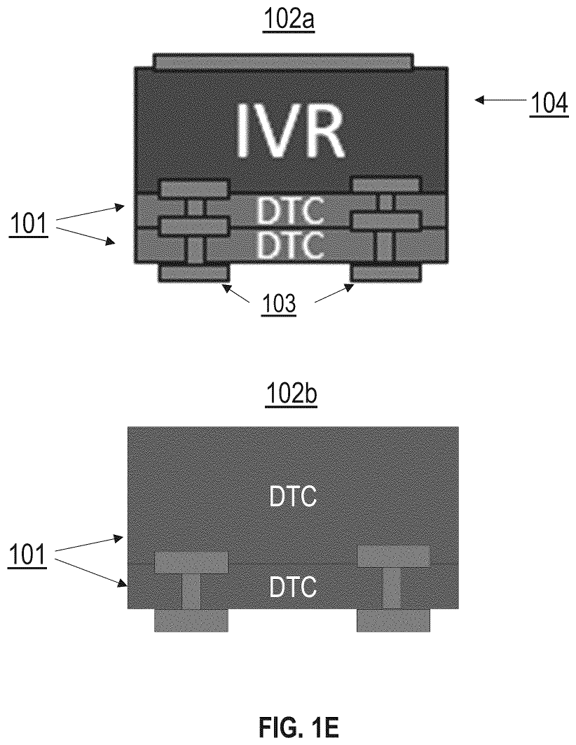

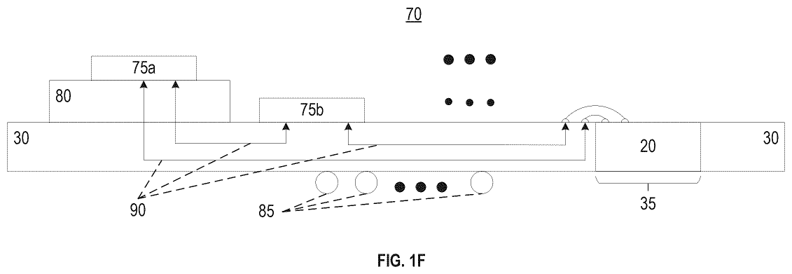

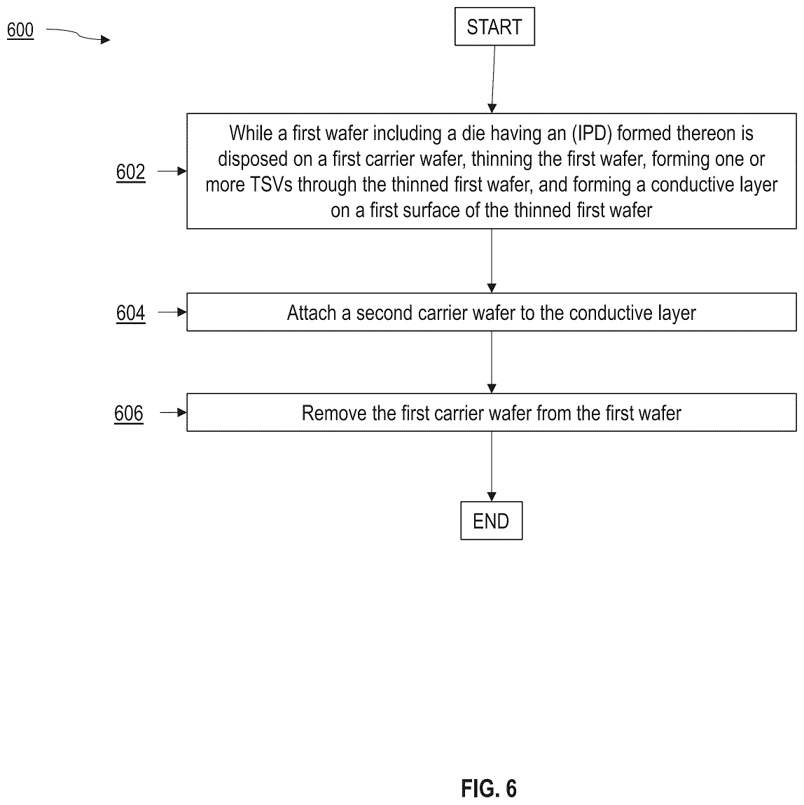

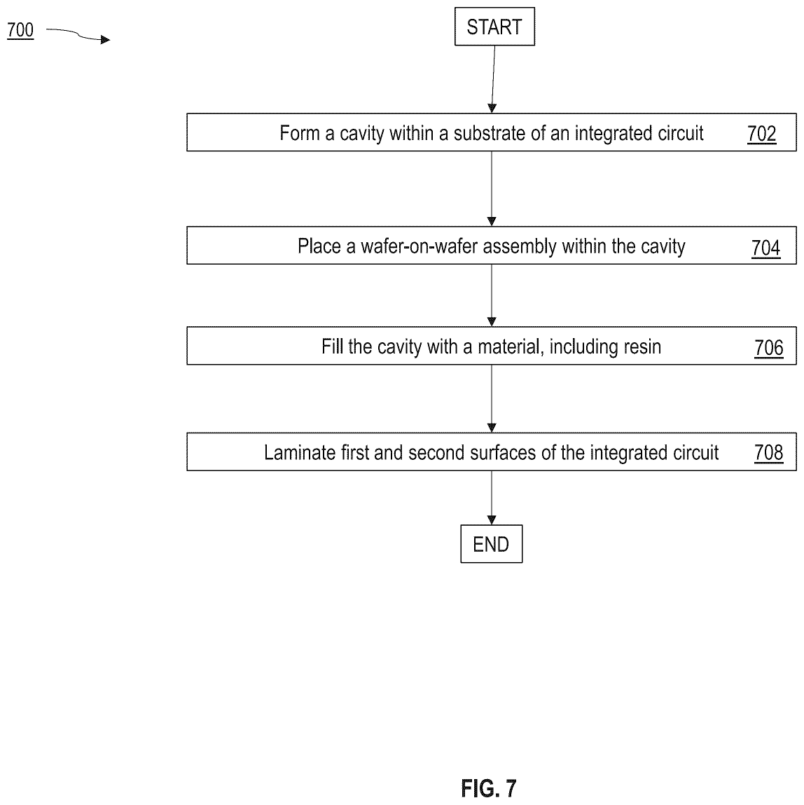

The following disclosure provides, with reference to FIGS. 1A-IF, 2-5, and 8-9, detailed descriptions of the devices produced by illustrative examples of wafer-on-wafer processes that can operate in accordance with techniques described herein. Detailed descriptions of corresponding wafer-on-wafer processes are provided in connection with FIGS. 6 and 7.

FIG. 1A shows an example device 10 having a wafer-on-wafer assembly 20 disposed in a cavity of a substrate 30. The wafer-on-wafer (WoW) assembly 20 includes a portion of a first wafer (e.g., a first die 22) and portion(s) of at least one wafer (e.g., at least one die 26) arranged in a stack and bonded together. In some examples, the WoW assembly 20 is manufactured using any suitable WoW process (e.g., any example of the WoW processes disclosed herein). In some examples, the first die 22 includes an integrated passive device (IPD). Examples of IPDs can include, without limitation, resistors, inductors, or capacitors (e.g., deep trench capacitors). In some examples, at least one through-silicon via (TSV) 24 is formed in the first die 22. The TSV(s) 24 can extend from a first surface of the first die to a second surface of the first die opposite the first surface.

In some examples, the at least one die 26 is a second die 26a, as shown in FIG. 1B. In some examples, the second die 26a includes another integrated passive device (IPD). In some examples, at least one through-silicon via (TSV) 27 is formed in the second die 26a. The TSV(s) 27 can extend from a first surface of the second die 26a to a second surface of the second die 26a opposite the first surface. In some examples, the second die 26a includes power delivery circuitry (e.g., an integrated voltage regulator (IVR)). In some examples, the second die 26a includes a thermal carrier die. The thermal carrier die can include heating elements and temperature sensors. For example, the power delivery circuitry can be attached to or embedded within the thermal carrier die.

In some examples, the at least one die 26 includes a second die 26b and a third die 26c, as shown in FIG. 1C. In some examples, the second die 26b includes another integrated passive device (IPD). In some examples, at least one through-silicon via (TSV) 28 is formed in the second die 26b. The TSV(s) 28 can extend from a first surface of the second die 26b to a second surface of the second die 26b opposite the first surface. In some examples, the third die 26c includes power delivery circuitry (e.g., an integrated voltage regulator (IVR)). In some examples, the third die 26c includes a thermal carrier die. The thermal carrier die can include heating elements and temperature sensors. For example, the power delivery circuitry can be attached to or embedded within the thermal carrier die. The dies 26b and 26c can be arranged in a stack and bonded together.

The first die 22 and at least one die 26 of the WoW assembly can be directly or indirectly bonded using any suitable type of adhesive or bond. In some examples, opposing surfaces of the first die 22 and a second die (e.g., second die 26a or 26b) are bonded directly to each other, without any other substrate or layer being interposed therebetween. Likewise, in some examples, opposing surfaces of the second die 26b and the third die 26c are bonded directly to each other. Such direct bonding can be achieved using fusion bonding techniques or any other suitable techniques. Alternatively, one or more additional substrates or layers can be interposed between the first die and the second die, or between the second die and the third die. Some non-limiting examples of techniques for bonding two or more wafers in a WoW assembly (e.g., hybrid bonding) are described herein.

Referring again to FIG. 1A, in some examples the WoW assembly 20 is disposed in a cavity 35 of a substrate 30. In some examples, the cavity 35 is formed in the central core of the substrate 30. In such examples, the substrate 30 may be referred to herein as a substrate core.

In some examples, the device 10 further includes a layer 40 of material below the WoW assembly 20 and the substrate 30. In some examples, the layer 40 includes prepreg material (e.g., fiberglass or other fibers impregnated with a partially cured resin such as epoxy). In some examples, the layer 40 is an insulating layer and the material includes dielectric material.

In some examples, the device 10 further includes a layer 60 of material above the WoW assembly 20 and the substrate 30. In some examples, the layer 60 includes prepreg material (e.g., fiberglass or other fibers impregnated with a partially cured resin such as epoxy). In some examples, the layer 60 is an insulating layer and the material includes dielectric material.

In some examples, the device 10 further includes cavity fill material 50 disposed in the portions of the cavity 35 that are not otherwise filled by the WoW assembly 20. Any suitable cavity fill material 50 can be used, e.g., underfill, resin (e.g., epoxy-based resin, silicone-based resin) dielectric paste, die attach film, etc.

FIGS. 1D and 1E illustrate block diagrams of example devices 100a, 100b, 102a, and 102b that can be formed during wafer-on-wafer manufacturing processes. In some examples, each of device 100b device 102a, and/or device 102b is an instance of the WoW assembly 20 illustrated in FIG. 1A.

FIG. 1D illustrates a cross-sectional view of an intermediate device 100a formed during a WOW manufacturing process. The intermediate device 100a includes a portion 121 of a first wafer (e.g., a portion that will become a die after dicing), a portion 126 of a carrier wafer, and a portion 127 of a conductive layer. The portion 121 of the first wafer can include at least one integrated passive device (IPD). Any suitable IPD(s) can be used including, without limitation, resistors, inductors, capacitors (e.g., deep trench capacitors), etc. One or more through-silicon vias (TSVs) can be formed in the portion 121 of the first wafer, and the IPD(s) can be connected (e.g., conductively coupled) to the portion 127 of the conductive layer via the one or more TSVs 103. The conductive layer can include any suitable conductive material. In some examples, the conductive layer is a metal layer. The portion 121 of the first wafer and the portion 127 of the conductive layer can be attached to a portion 126 of a carrier wafer.

In some examples, the portion 121 of the first wafer includes one or more deep trench capacitors (DTCs), and the TSVs 103 connect (e.g., conductively couple) the DTCs of the portion 121 of the first wafer to the portion 127 of the conductive layer. In some examples, after further assembly whereby the DTCs are conductively coupled to other components via the portion 127 of the conductive layer, the deep trench capacitor(s) can provide steady power and store excess power during operation of those other components to meet power delivery or power discharge requirements during a surge in the amount of current drawn or discharged by those other components.

In some examples, the conductive layer can include one or more conductive materials. In some implementations, the conductive layer can be formed on the first wafer by forming a plurality of structures using any suitable integrated circuit fabrication techniques including, without limitation, deposition, metallization, masking, and/or etching techniques. In certain implementations, the conductive layer can include one or metals. In certain examples, the one or more conductive materials can have a predetermined thickness. In certain implementations, the conductive layer can reduce power loss that occurs in transformers due to coil resistance (sometimes described as “copper loss”).

In some examples, the device 100a further includes a portion 129 of a bonding layer configured to facilitate bonding of a portion of a second wafer to the portion 121 of the first wafer via the bonding layer. In some examples, the bonding layer is a silicon layer.

In certain implementations, the carrier wafer is a temporary carrier wafer mounted to the conductive layer. The temporary carrier wafer can be a sacrificial wafer that that is thicker than non-sacrificial wafers. In one implementation, the carrier wafer is disposed on the conductive layer such that the carrier wafer is opposite the first wafer.

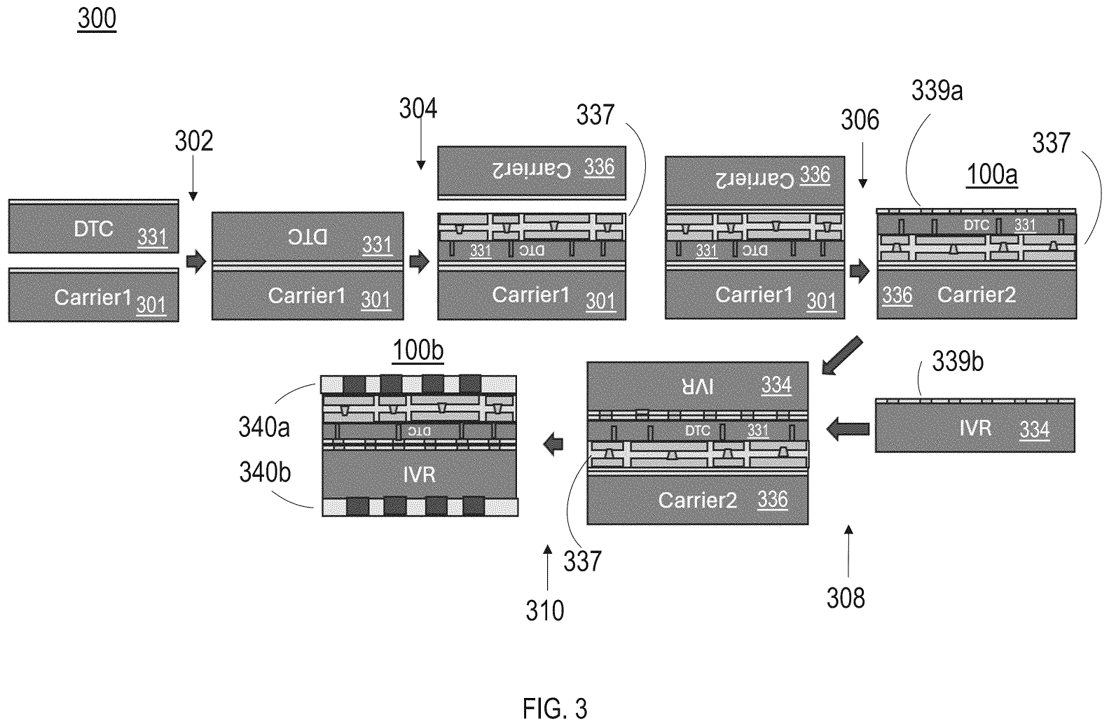

FIG. 1D also illustrates a cross-sectional view of a device 100b (e.g., a WoW assembly 20) that includes a first die 101 (with one or more IPDs and one or more TSVs 103), a second die 104, a conductive layer 107, one or more bonding layers 109, and pad layers 110a, 110b. In some examples, the device 100b is assembled by performing steps of the WOW manufacturing process 300 of FIG. 3 using a first assembly that includes the intermediate device 100a and a second wafer. In some examples, the second die 104 includes power delivery circuitry (e.g., an integrated voltage regulator (IVR)) or any other suitable circuitry. In some examples, the power delivery circuitry is configured to switch power between one or more controllers. In some implementations, the power delivery circuitry is fabricated using a seven-nanometer silicon process node. In some examples, the second die 104 includes a bonding layer 109 suitable for bonding the second die 104 to the first die 101. In some examples, the bonding layer of the second die 104 is a silicon layer.

In some implementations, the components of the device 100b are assembled such that the bonding layers 109 of the first and second dies are adjacent, and the first die 101 and second die 104 are disposed opposite each other and bonded to each other through the bonding layers. In one example, the bond between the first and second dies formed via the bonding layers (e.g., silicon substrate interface) is a hybrid bond.

In some examples, the pad layers 110a, 110b include polyimide layers that provide an efficient heat transfer from the second die 104 (away from the device 100b) and an efficient electrical transfer of signals from the first die 101 to off-chip components. In one example, the pad layers are positioned on distal ends of the device 100b. In some examples, the pad layers include landing spaces (e.g., vias) on both sides to provide for the passive electrical connections with the one or more TSVs 103. In certain implementations, the addition of the pad layers occurs during packaging of the device 100b.

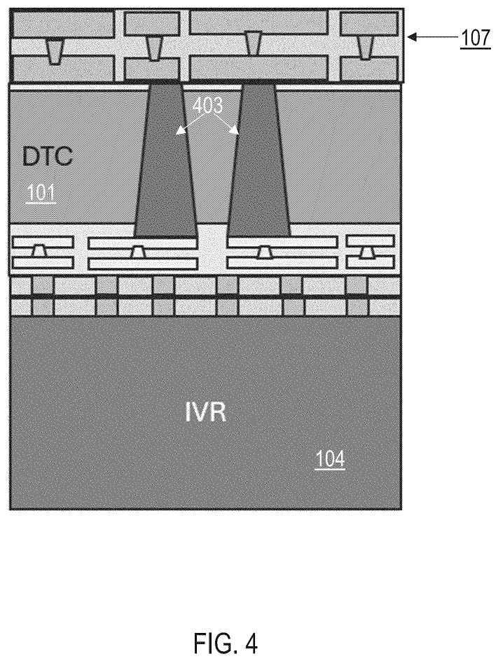

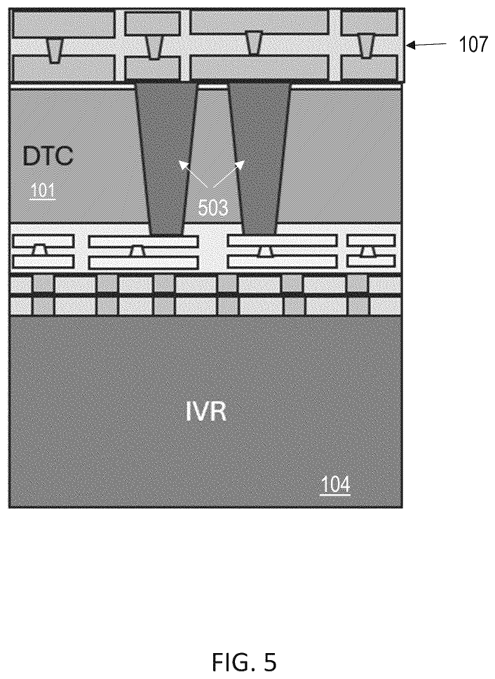

In some implementations, the one or more TSVs 103 have a particular shape and direction (e.g., orientation). Some non-limiting examples of TSV shapes and orientations are described below with reference to FIGS. 4-5.

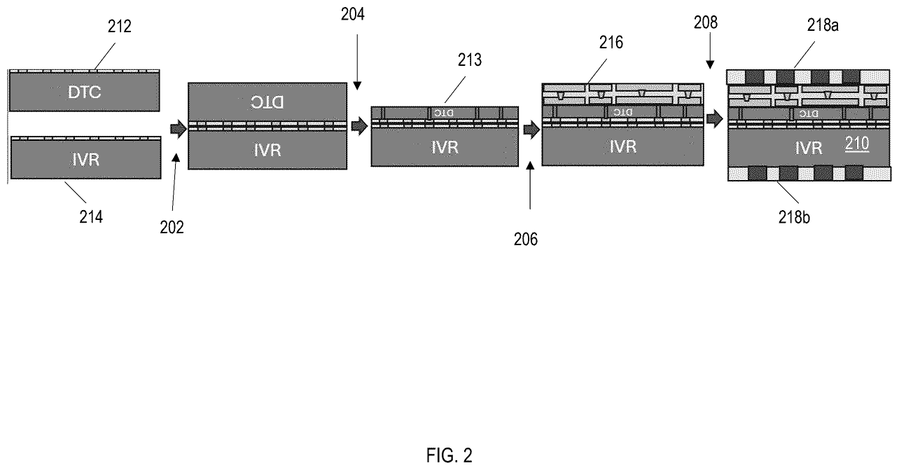

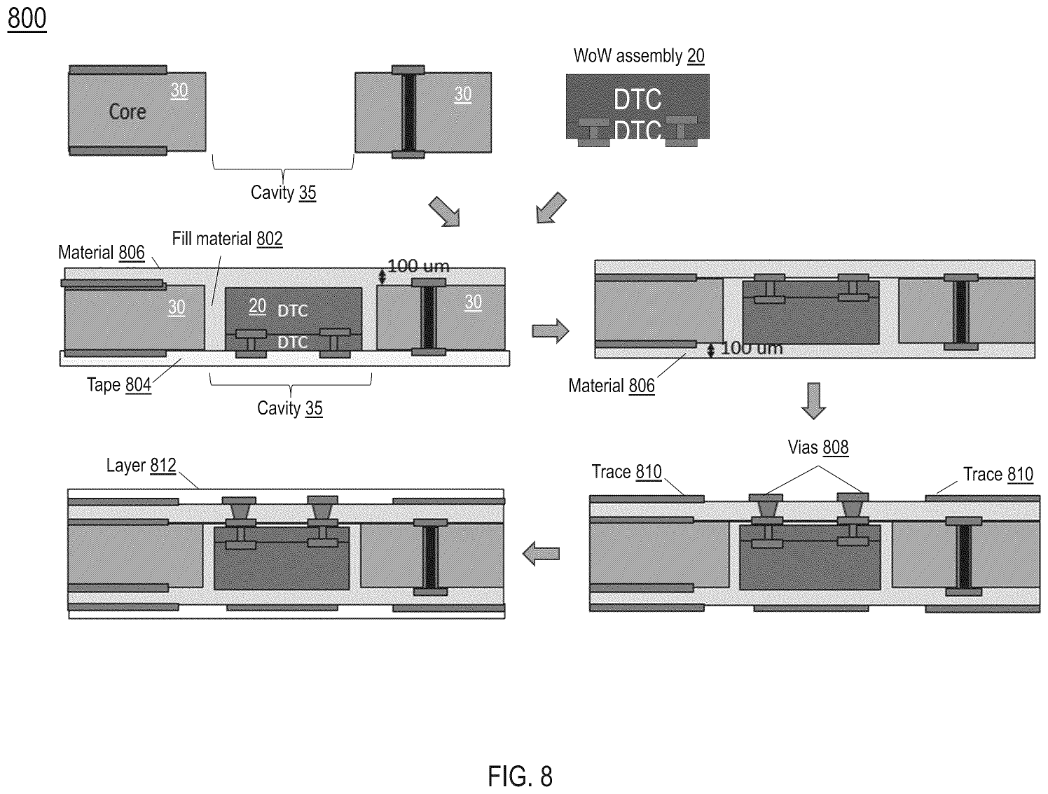

Some non-limiting examples of WOW manufacturing processes for assembling the device 100a and the device 100b (e.g., WoW assembly) are described herein (e.g., with reference to FIGS. 2-6). Some non-limiting examples of processes for integrating the device 100b into a cavity in a substrate of a device 10 are also described herein (e.g., with reference to FIGS. 7-8).

FIG. 1E illustrates a cross-sectional view of a device 102a (e.g., WoW assembly) that includes a stack of one or more first dies 101 and a second die 104. Each of the first die 101 can include at least one integrated passive device (IPD). The IPD can be, for example, an inductor, a resistor, or a capacitor (e.g., deep trench capacitor). The second die 104 can include power delivery circuitry (e.g., an integrated voltage regulator (IVR)) or any other suitable circuitry. One or more through-silicon vias (TSVs) can be formed through the first die(s), and the circuitry of the second die can be connected (e.g., conductively coupled) to the IPD(s) of the first die(s) via the TSVs 103.

FIG. 1E also illustrates a cross-sectional view of a device 102b (e.g., WoW assembly) that includes two or more stacked first dies 101. Each of the first dies 101 can include at least one integrated passive device (IPD). The IPD can be, for example, an inductor, a resistor, or a capacitor (e.g., deep trench capacitor). One or more TSVs 103 can be formed through the first die(s), and the IPDs of the first die(s) can be connected (e.g., conductively coupled) to each other via the TSVs 103.

Some non-limiting examples of WOW manufacturing processes for assembling the devices 102a and 102b (e.g., WoW assemblies) are described herein (e.g., with reference to FIGS. 7-8). Some non-limiting examples of processes for integrating the devices 102a and 102b into a cavity of a substrate of a device 10 are also described herein (e.g., with reference to FIGS. 7-8).

In some examples, the first die 101 of any of the devices of FIG. 1D or FIG. 1E can have a predetermined thickness and/or interface with different components and/or structures. This predetermined thickness can match the size of the thickness of one or more additional first wafers (e.g., wafers having IPDs fabricated thereon). In some examples, the thickness of a WoW assembly 20 (e.g., device 100b, 102a, or 102b) can match the depth of cavity 35 formed in the substrate 30 of a device 10. In some examples, the first die 101 can include, incorporate, or be connected to one or more discrete components, which can correspond to passive components such as capacitors, inductors, etc. In certain implementations, the first die can have a minimum thickness of 65 nanometers and a maximum thickness of 130 nanometers.

FIG. 1F illustrates an example of a multi-chip package 70. Multi-chip packages are sometimes described as “hybrid integrated circuits” or “advanced packages.” In the example of FIG. 1F, multi-chip package 70 includes a wafer-on-wafer assembly 20 disposed in a cavity 35 of a substrate 30, as well as one or more additional integrated circuits (e.g., chiplets). The substrate 30 can be a substrate of the package (e.g., a core substrate of a printed circuit board), a substrate of an integrated circuit, or any other suitable substrate. In some examples, at least one integrated circuit 75b is disposed on the substrate 30. In some examples, at least one integrated circuit 75a is disposed on an interposer 80 disposed on the substrate 30.

In some examples, the WOW assembly 20 is communicatively coupled to some or all of the other integrated circuits via one or more interconnects 90 (e.g., traces, vias, bumps, pins, etc.). The interconnects 90 can be routed through or on the surface of the interposer 80 and/or through or on the surface of the substrate 90. In some examples, the WOW assembly 20 and the other integrated circuits can communicate with each other via the interconnects 90 using any suitable communication standard or protocol including, without limitation, Universal Chiplet Interconnect Express (UCIe), bunch of wires (BoW), Open High Bandwidth Interconnect (OpenHBI), the Optical Internetworking Forum (OIF) Extra Short Reach (XSR), etc. In some examples, the multi-chip package 70 also includes package-level pins 85 (e.g., balls of a ball grid array).

FIG. 2 is a flow diagram of an example of a wafer-on-wafer manufacturing process 200 for assembling a device 210, which includes a first die including at least one capacitor and a second die including power delivery circuitry.

As illustrated in FIG. 2, at step 202 the manufacturing process 200 attaches a first wafer 212, which includes dies each including one or more integrated passive devices, to a second wafer 214, which includes dies each including power delivery circuitry. For example, a die of the first wafer can include a deep trench capacitor (DTC) and a die of the second wafer can include an integrated voltage regulator (IVR). Any suitable technique can be used to attach (e.g., bond) the first and second wafers.

At step 204, the manufacturing process 200 thins the first wafer 212 and forms one or more through-silicon vias (TSVs) in each die of the thinned first wafer 213. In some examples, the TSV(s) connect (e.g., conductively couple) the IPDs of dies of the first wafer to the power delivery circuitry of dies of the second wafer.

At step 206, the manufacturing process 200 forms a conductive layer 216 on the thinned first wafer via any suitable deposition, patterning, metallization, etching, and/or masking techniques. In some implementations, the conductive layer is formed on the thinned first wafer such that the conductive layer is positioned opposite the second wafer. In some examples, the conductive layer can include one or more metals with any suitable thickness.

At step 208, the manufacturing process 200 attaches one or more pad layers 218a, 218b to each distal end of the assembly. In some implantations, the one or more pad layers can correspond to polyimide layers that provide an efficient heat transfer. In one example, the polyimide layers can include landing vias on each end that provide electrical connections and provide thermal heat transfer pads. The pad layers can be attached before or after dicing the bonded wafer stack into individual devices 210.

The wafer-on-wafer manufacturing process 200 of FIG. 2 can lead to longer cycle times as the fabrication of the power delivery circuitry on the dies of the second wafer can be time consuming and complex, but the step 204 of thinning the first wafer and the step 206 of forming the conductive layer on the thinned first wafer occur after the fabrication of the second wafer and the bonding of the two wafers to each other. Theoretically, thinning the first wafer and forming the conductive layer on the thinned first wafer before bonding the first and second wafers can reduce the cycle time of the manufacturing process, but thinning the first wafer 213 prior to bonding the first wafer 213 to the second wafer 214 can lead to lower yields and defects in the first wafer.

FIG. 3 is a flow diagram of an example manufacturing process 300 for assembling a device 100b in accordance with techniques described herein. The steps illustrated in FIG. 3 can be performed using any suitable device semiconductor fabrication/manufacturing/assembly systems or equipment. In one example, one or more of the steps illustrated in FIG. 3 can be implemented using a process that includes multiple sub-steps, examples of which are provided in greater detail below.

As illustrated in FIG. 3, at step 302 a first wafer 331 is attached (e.g., bonded to or mounted to) a first carrier wafer 301. The first wafer 331 can include dies, each of which can include one or more IPDs (e.g., one or more DTCs). The first carrier wafer 301 can be a temporary carrier wafer and/or a sacrificial carrier wafer. In one example, the act of bonding of the first wafer 331 and the first carrier wafer 301 can involve positioning a surface of a silicon substrate (e.g., a silicon substrate interface) of the first wafer 331 opposite a silicon substrate interface of the first carrier wafer 301 and bonding or attaching the interfaces to each other.

At step 304, after attaching the first wafer 331 to the first carrier wafer 301, one or more of the systems described herein thin the first wafer 331, form one or more TSVs through the first wafer 331, and form a conductive layer 337 on a surface of the first wafer 331 opposite the surface of the first wafer 331 that is bonded to the first carrier wafer 301. In some examples, after forming the conductive layer 337 on the first wafer 331, a second carrier wafer 336 is attached to the first wafer 331 on a surface of the first wafer 331 opposite the first carrier wafer 301 (e.g., the surface of the first carrier wafer 301 on which the conductive layer 337 is formed). In some implementations, the conductive layer 337 can be formed by any suitable semiconductor fabrication techniques (e.g., deposition, metallization, patterning, masking, and/or etching techniques), such that the conductive layer 337 includes one or more vias, contacts, traces, etc. In some implementations, the conductive layer 337 is electrically coupled to the first wafer 331 by the one or more TSVs. In some examples, the conductive layer can include any suitable conductive material (e.g., copper).

At step 306, one or more of the systems described herein can remove the first carrier wafer 301 from the thinned first wafer 331. In some implementations, the removal of the first carrier wafer 301 can refer to detaching the first carrier wafer 301 from the thinned first wafer 331. In some examples, the removal of the first carrier wafer 301 can refer to etching the first carrier wafer 301 away from the thinned first wafer 331. In some examples, the removal of the first carrier wafer 301 from the thinned first wafer 331 can produce the device 100a that is an intermediate result of the wafer-on-wafer manufacturing process 300. In some examples, step 306 can further involve forming a bonding layer 339a on a surface of the first wafer 331. The bonding layer 339a can be suitable for forming a hybrid bond between the bonding layer 339a and a bonding layer of another wafer. In some implementations, the device 100a can be stored for subsequent processing while a second wafer 334 is fabricated. In other implementations, the remaining steps of the manufacturing process 300 can be performed without storing the device 100a.

At step 308, one or more of the systems described herein dispose a second wafer 334 on the thinned first wafer 331. In one example, the second wafer 334 is attached to the thinned first wafer 331 such that the second wafer 334 is positioned opposite the second carrier wafer 336. In some examples, the conductive layer 337 can be positioned between the thinned first wafer 331 and the second carrier wafer 336. The second wafer 334 can include dies, each of which can include power delivery circuitry (e.g., an IVR) or any other suitable circuitry. In some examples, the second wafer 334 can include a bonding layer 339b, which can be formed on a surface of the second wafer 334. In some examples, attaching the thinned first wafer 331 to the second wafer 334 involves bonding (e.g., hybrid bonding) the two wafers along the surfaces of the bonding layers 339a and 339b.

At step 310, one or more of the systems described herein remove the second carrier wafer 336 from the bonded first and second wafers, and attach one or more padded layers 340a, 340b to distal surfaces of the first wafer 331 and the second wafer 334. In some examples, the padded layers are attached to the second wafer 334 and the conductive layer 337 of the thinned first wafer 331 such that the thinned first wafer 331 is between the second wafer 334 and the conductive layer 337. In one example, a thermal transfer pad layer is attached to the conductive layer 337 and an electrical transfer pad layer is attached to the second wafer 334. The padded layers can be attached before or after dicing the bonded wafer stack into individual devices 100b. The devices 100b that result from performing the manufacturing process 300 can be WoW assemblies 20.

FIG. 4 illustrates a cross-sectional view of an example of a device 400 having one or more angled TSVs 403, which can be formed in a manufacturing process in accordance with some techniques described herein. The device 400 shown in FIG. 4 can be formed by suitable device manufacturing/fabricating systems, such as known or to-be-developed semiconductor wafer manufacturing equipment.

FIG. 4 illustrates a cross-sectional view of a device 400 that includes one or more TSVs 403 in a middle configuration within the first die 101. In some implementations, the one or more TSVs 403 can correspond with a particular angled shape and direction with a base near the second die 104 and a head near the conductive layer 107. In some implementations, the middle configuration of the TSV can refer to a configuration where a base of the TSV has a larger diameter than a head of the TSV, where the base of the TSV is closer in proximity than the head to the second die 104, and the head of the TSV is closer in proximity than the base to the conductive layer 107. In some examples, the TSV middle configuration can correspond to a slope (e.g., a tapered angle) associated with each edge of the TSV within the first die 101 and can couple through a front side of the first die 101. In one example, the TSV can correspond to a middle configuration with an angular profile. In some implementations, the angle and direction of the TSV can provide information corresponding to the manufacturing process associated with the first die 101 and the TSV.

FIG. 5 illustrates another example of a through-silicon via configuration within a device 500. As illustrated in FIG. 5, a manufacturing process forms a device 500 that includes a conductive layer 107 formed on a first die 101 (e.g., a die on which a deep trench capacitor is formed) having through-silicon vias 503, where the first die 101 is connected to a second die 104 (e.g., a die on which a power delivery circuit is formed). In device 500, the through-silicon via 503 has a base that is larger in diameter than a head of the through-silicon via, where the base is closer in proximity than the head to the conductive layer 107, and the head is closer in proximity than the base to the power delivery circuit of the second die 104.

FIG. 6 is a flow diagram of an example wafer-on-wafer manufacturing method 600. In some examples, the method 600 includes steps 602-606.

In step 602, while a first wafer 331 is disposed on a first carrier wafer 301, the first wafer is thinned, one or more through-silicon vias (TSVs) are formed through the thinned first wafer, and a conductive layer 337 is formed on a first surface of the thinned first wafer (opposite a second surface of the thinned first wafer to which the first carrier wafer is attached). In some examples, the first wafer 331 includes at least one die including at least one integrated passive device (IPD), for example, a deep trench capacitor.

In step 604, a second carrier wafer 336 is attached to the at least one conductive layer 337. In some examples, the second carrier wafer 336 and the first wafer 331 are positioned on opposite sides of the at least one conductive layer 337.

In step 606, the first carrier wafer 301 is removed from the first wafer 331. In some examples, removing the first carrier wafer 301 from the first wafer 331 facilitates formation of one or more additional layers on the first wafer 331 and/or attachment of one or more additional wafers to the first wafer.

In some examples, the method 600 further includes steps of bonding (e.g., hybrid bonding) a second wafer 334 to the first wafer 331, and removing the second carrier wafer 336 from the wafer-on-wafer assembly. In certain implementations, the first carrier wafer 301 and the second carrier wafer 336 can be thermal carrier wafers.

FIG. 7 is a flow diagram of an example method 700 for assembling a device with a wafer-on-wafer assembly disposed in a cavity of a substrate of the device. Steps of the method 700 are also illustrated in the flow diagram of FIG. 8.

In step 702, a cavity 35 is formed within (e.g., through) a substrate 30 (e.g., a substrate core) of an integrated circuit. In some examples, the cavity is formed via a drilling process. In some examples, the depth of the cavity matches the thickness of the substrate.

In step 704, a wafer-on-wafer assembly 20 is inserted in the cavity 35. The WoW assembly 20 can include a first die 22 and one or more second dies 26. The first die can be conductively coupled to the one or more second die via one or more through-silicon vias (TSVs) 24 formed through the first die 22. Some non-limiting examples of WoW assemblies 20 are described with reference to FIGS. 1A-1E.

In step 706, the portions of the cavity not occupied by the WoW assembly 20 can be filled with fill material 802, which can include resin. In certain implementations, the filling of the cavity with the resin material can encapsulate the components of the WoW assembly 20 placed within the cavity, thereby providing mechanical support, electrical insulation from other components of the integrated circuit, and/or thermal coupling to other components of the integrated circuit. In certain implementations, the fill material can further include mold compounds and/or composite materials associated with a desired thermal and/or mechanical property. In some examples, prior to filling the cavity 35 with material, tape 804 can be applied (e.g., laminated) to a first side of the substrate 30 and the cavity 35.

In step 708, first and second layers of a material 806 (e.g., prepreg material) can be laminated to first and second surfaces of the integrated circuit. In some examples, prior to laminating the layer of material to the first surface of the integrated circuit, a tape previously laminated to the first surface of the integrated circuit is removed.

In some examples, the method 700 further includes forming vias 808 and/or traces 810 in the laminated material. In some examples, these vias and/or traces include copper material, which can be configured to couple the WoW assembly 20 to other components of the integrated circuit (e.g., one or more adjacent magnetic inductors of a magnetic inductor array, also disposed in the cavity 35). In some examples, the method 800 further includes forming one or more additional layers 812 on the integrated circuit (e.g., on the material 806).

FIG. 8 a flow diagram of an example method 800 for assembling a device with a wafer-on-wafer assembly disposed in a cavity of a substrate of the device.

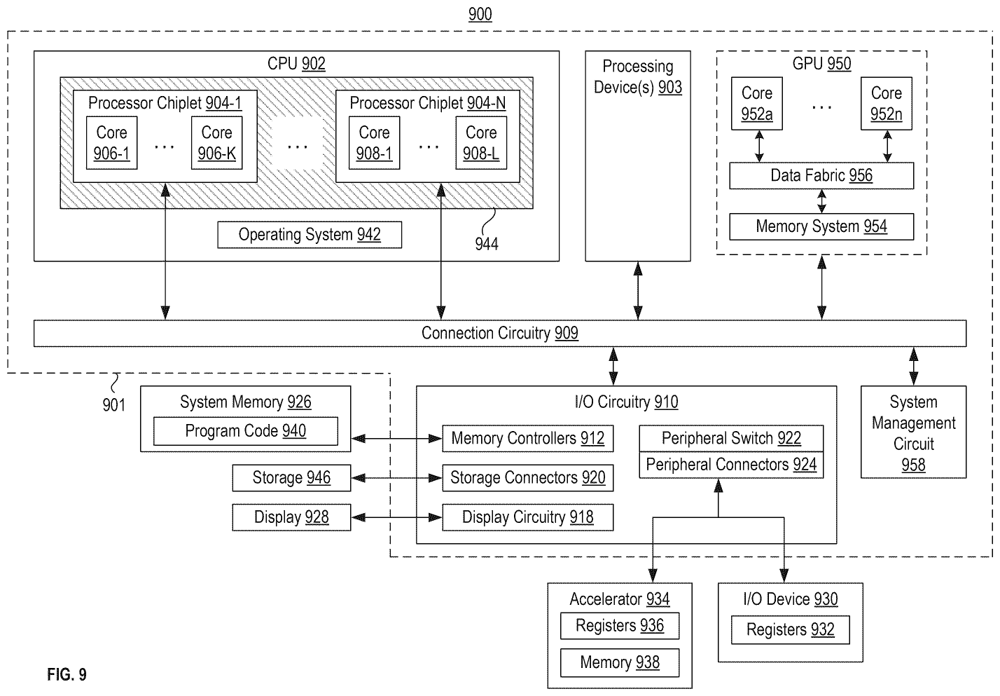

FIG. 9 illustrates one exemplary implementation of a computer system 900 configured to implement the techniques described herein, although others are possible. It should be appreciated that FIG. 9 is intended neither to be a depiction of necessary components for a computer system 900 to operate in accordance with the principles described herein, nor a comprehensive depiction.

Computer system 900 can be, for example, a desktop computer, a video game console, a server, a wireless access point or other networking element, a mobile computing device (e.g., laptop computers, tablets, smartphones, smartwatches, implantable health monitoring devices, wearable computers, personal digital assistants, etc.), or any other suitable computing system. Computer system 900 can comprise at least one central processing unit (CPU) 902, one or more processing devices 903 (e.g., graphics processing unit (GPU), accelerated processing unit (APU), vision processing unit (VPU), tensor processing unit (TPU), physics processing unit (PPU), digital signal processing (DSP) circuit, field programmable gate array (FPGA), application-specific integrated circuit (ASIC), etc.), connection circuitry 909, I/O circuitry 910, system memory 926, at least one I/O device 930, at least one accelerator 934, storage 946 (e.g., computer-readable storage media), and/or at least one display 928. In some examples, the CPU 902, processing device(s) 903, connection circuitry 909, and I/O circuitry 910, are coupled to (e.g., mounted on) a printed circuit board (e.g., motherboard) 901.

CPU 902 enables processing of data and execution of instructions. The data and instructions can be stored on system memory 926, storage 946, and/or internal memory (not shown) of the CPU 902. In some examples, the CPU 902 includes one or more processor chiplets 904-1 . . . 904-N, which may be disposed on or over a package substrate 944. In some examples, the processor chiplets can communicate with each other via interconnects routed through or on the package substrate 944 (e.g., through an interposer layer disposed between the package substrate 944 and the processor chiplets). In some examples, each processor chiplet includes one or more cores (906, 908). Different processor chiplets can have the same or different numbers of cores (906, 908). In the example of FIG. 9, processor chiplet 904-1 has K cores 906-1 . . . 906-K, and processor chiplet 904-N has L cores (908-1, 908-2, . . . 908-L). The cores within an individual processor chiplet (e.g., cores 906-1 . . . 906-K) can be homogeneous or heterogeneous. Likewise, the cores on different processor chiplets (e.g., cores 906-1 and 908-1) can be homogeneous or heterogeneous.

In the example of FIG. 9, the CPU 902 is configured to execute instructions of an operating system 942 and/or instructions (e.g., program code 940) of one or more applications. In some examples, the functionality of the program code may be implemented by one or more processing devices 903, one or more CPUs 902, one or more processor chiplets of a CPU 902, and/or one or more cores of a processor chiplet.

The data and instructions stored on any of the computer-readable storage media (e.g., system memory 926, storage 946, accelerator memory 938, internal or external caches of the CPU 902, etc.) can comprise computer-executable instructions implementing any suitable functionality.

In some examples, connection circuitry 909 communicatively couples CPUs 902 with each other, with processing device(s) 903, and/or with external caches (e.g., level-2 (L2) cache, level-3 (L3) cache, etc.). Additionally, or alternatively, the connection circuitry 909 can communicatively couple the CPUs 902 with I/O circuitry 910, which communicatively couples system memory, storage devices, and peripheral devices to each other and (via the connection circuitry 909) to the CPUs 902. The connection circuitry can couple the CPUs 902, external caches, and I/O circuitry 910 using any suitable network topology (e.g., a front-side bus, a back-side bus, etc.), and the coupled components can send and receive messages via the connection circuitry using any suitable communication protocol. In some examples, portions of the connection circuitry 909 can be integrated into the CPU(s) 902 and/or processing device(s) 903.

In some examples, I/O circuitry 910 includes one or more memory controllers 912, one or more storage connectors 920, display circuitry 918, one or more peripheral connectors 924, and a peripheral switch 922. The memory controller(s) 912 can be configured to control the flow of data to and from the system memory 926. The storage connector(s) 920 can be configured to control the flow of data to and from the storage 946. The display circuitry 918 can be configured to send visual data (e.g., user interface data, image data, video data, etc.) to the display 928, which can be configured to display the visual data. In some examples, the display circuitry 918 can also be configured to receive data representing user input from the display 928 (e.g., in cases where the display 928 includes a touchscreen). In some examples, portions of the I/O circuitry 910 can be integrated into a motherboard and/or motherboard chipset (e.g., I/O circuitry 910) of the computer system 900.

Each of the peripheral connectors 924 may be configured to physically connect and communicatively couple the I/O circuitry 910 to a peripheral device. Any suitable type of peripheral device can be connected to a peripheral connector 924 including, without limitation, an I/O device 930 (e.g., an input device, output device, or input/output device), an accelerator 934, etc. Some non-limiting examples of an input device can include a mouse, keyboard, scanner, video game controller, microphone, webcam, etc. Some non-limiting examples of an output device can include a display, printer, speakers, headphones, earbuds, etc. Some non-limiting examples of an input/output device can include a storage device (e.g., disk drive, solid-state drive, universal serial bus (USB) flash drive, memory card, tape drive, etc.), a networking device (e.g., modem, router, gateway, network adapter, access point, etc.), etc. A networking adapter can be any suitable hardware and/or software to enable the computer system 900 to communicate via wires and/or wirelessly with any other suitable computing system over any suitable computing network. The computing network can include wireless access points, switches, routers, gateways, and/or other networking equipment as well as any suitable wired and/or wireless communication medium or media for exchanging data between two or more computers, including the Internet. Optionally, an I/O device can include one or more registers 932. In some examples, the I/O circuitry 910 can control the operation of an I/O device 930 by writing suitable data to one or more of the I/O device's registers, and/or can monitor the status of an I/O device 930 by reading the contents of one or more of the I/O device's registers.

Some non-limiting examples of an accelerator 934 can include a graphics processing unit (GPU), accelerated processing unit (APU), vision processing unit (VPU), tensor processing unit (TPU), physics processing unit (PPU), digital signal processing (DSP) circuit, field programmable gate array (FPGA), application-specific integrated circuit (ASIC), etc. In some examples, an accelerator 934 includes one or more registers 936 and memory 938. In some examples, the I/O circuitry 910 can control the operation of an accelerator 934 by writing suitable data to one or more of the accelerator's registers, and/or can monitor the status of an accelerator 934 by reading the contents of one or more of the accelerator's registers.

The peripheral switch 922 can be configured to switch packets sent to or from the peripheral devices. Any suitable type of peripheral connector(s) 924 and peripheral switch 922 can be used including, without limitation, universal serial bus (e.g., USB-A, USB-B, USB-C, USB-3.0, etc.), Ethernet, DisplayPort, high-definition multimedia interface (HDMI), peripheral component interconnect (PCI), peripheral component interconnect extended (PCI-X), peripheral component interconnect express (PCIe), accelerated graphics port (AGP), etc.

As described above computer system 900 can have one or more components and peripherals, including input and output devices. These devices can be used, among other things, to present a user interface. Examples of output devices that can be used to provide a user interface include printers or display screens for visual presentation of output and speakers or other sound generating devices for audible presentation of output. Examples of input devices that can be used for a user interface include keyboards, and pointing devices, such as mice, touch pads, and digitizing tablets. As another example, a computing device can receive input information through speech recognition or in other audible format.

Continuing with FIG. 9, in some examples, the connection circuitry 909 communicatively couples a GPU 950 and a system management circuit 958 with the other components of the system 900. The GPU 950 can include at least one or more cores 952a . . . 952n, a memory system 954, and a data fabric 956. The cores 952a . . . 952n can be configured to perform parallel processing for various applications, similar to the cores 906-1 to 908-L. The use of the cores 952a . . . 952n is frequently beneficial when performing certain tasks. Examples of applications that benefit from using GPU processing can include graphics processing, machine learning, artificial intelligence, blockchain and/or cryptocurrency processing, etc. The memory system 954 can include a set of memory cells and/or chiplets, which can be partitioned into logical or physical subsets (e.g., channels). The memory system 954 can include the hardware, software and firmware configured to route memory access commands from the interface to at least one memory channel of the plurality of memory channels. For example, memory system 954 can include a combination of memory cells, voltage rail(s), direct memory access (DMA) controller, buffers, memory controller, etc. Each of the components of the GPU 950 can include other subsets of components. For example, the memory controller can include physical interface circuits (PHYs), phase locked loop(s), and other components needed to store and process data. In certain embodiments, the memory system 954 can include an exemplary stack of dynamic random-access memory chiplets, where each chiplet can be mounted vertically to at least one of a logic die and/or another memory chiplet. The GPU 950 can also include other components not depicted, for example, clocks, cooling components, voltage regulators, I/O interfaces, etc.

In some examples, the data fabric 956 includes a combination of on-chip routing components that mediate access to system memory by the CPU, the GPU, and other ‘clients’ (such as the display). Functionality implemented by the data fabric 956 can include, without limitation, queuing memory access requests when the requests exceed the bandwidth to memory (or to an individual memory channel), routing data from cores, clients, etc. to memory for write requests, routing data from memory to cores, clients, etc. for read requests, allocating portions of the memory bandwidth to different cores, clients, etc. (e.g., allocating all the memory bandwidth to the display client during the channel-partitioned training of the memory clock), doing virtual-to-physical address translation, etc.

In some examples, the system management circuit 958 can include a combination of hardware, software and firmware to assist in controlling storage, communications, timing, frequency, etc. within the system 900 and/or between parts of the system 900 and other systems (e.g., client devices). In one example, the system management circuit 958 can include power management firmware (PMFW) to assist in such operations. In some examples, the system management circuit 958 can set performance states of GPU 950 and can boost a first performance state of GPU 950 based on a variety of factors (e.g., client demands, temperature, power consumption, etc.).

In some examples, one or more of the components of the computer system 900 include a WOW assembly 20 or a device 10 with a WoW assembly disposed in a cavity of a substrate of the device. For example, the device 10 or WOW assembly can be included in CPU 902 (or in a processor chiplet or core thereof), in a processing device 903, in a GPU 950 (or in a core thereof), etc.

As detailed above, the circuits, devices, and systems described and/or illustrated herein broadly represent any type or form of computing device or system capable of executing computer-readable instructions. In their most basic configuration, these computing device(s) each include at least one memory device and at least one physical processor.

In some examples, the term “memory device” generally refers to any type or form of volatile or non-volatile storage device or medium capable of storing data and/or computer-readable instructions. In one example, a memory device stores, loads, and/or maintains one or more of the modules and/or circuits described herein. Examples of memory devices include, without limitation, Random Access Memory (RAM), Read Only Memory (ROM), flash memory, Hard Disk Drives (HDDs), Solid-State Drives (SSDs), optical disk drives, caches, variations, or combinations of one or more of the same, or any other suitable storage memory.

In some examples, the term “physical processor” generally refers to any type or form of hardware-implemented processing unit capable of interpreting and/or executing computer-readable instructions. In one example, a physical processor accesses and/or modifies one or more modules stored in the above-described memory device. Examples of physical processors include, without limitation, microprocessors, microcontrollers, Central Processing Units (CPUs), Field-Programmable Gate Arrays (FPGAs) that implement softcore processors, Application-Specific Integrated Circuits (ASICs), systems on a chip (SoCs), digital signal processors (DSPs), Neural Network Engines (NNEs), accelerators, graphics processing units (GPUs), portions of one or more of the same, variations or combinations of one or more of the same, or any other suitable physical processor.

In some implementations, the term “computer-readable medium” generally refers to any form of device, carrier, or medium capable of storing or carrying computer-readable instructions. Examples of computer-readable media include, without limitation, transmission-type media, such as carrier waves, and non-transitory-type media, such as magnetic-storage media (e.g., hard disk drives, tape drives, and floppy disks), optical-storage media (e.g., Compact Disks (CDs), Digital Video Disks (DVDs), and BLU-RAY disks), electronic-storage media (e.g., solid-state drives and flash media), and other distribution systems.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

The term “approximately”, the phrase “approximately equal to”, and other similar phrases, as used in the specification and the claims (e.g., “X has a value of approximately Y” or “X is approximately equal to Y”), should be understood to mean that one value (X) is within a predetermined range of another value (Y). The predetermined range may be plus or minus 20%, 10%, 5%, 3%, 1%, 0.1%, or less than 0.1%, unless otherwise indicated.

Measurements, sizes, amounts, etc. may be presented herein in a range format. The description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as 10-20 inches should be considered to have specifically disclosed subranges such as 10-11 inches, 10-12 inches, 10-13 inches, 10-14 inches, 11-12 inches, 11-13 inches, etc.

The indefinite articles “a” and “an,” as used in the specification and in the claims, unless clearly indicated to the contrary, should be understood to mean “at least one.” The phrase “and/or,” as used in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of or “exactly one of,” or, when used in the claims, “consisting of,” will refer to the inclusion of exactly one element of a number or list of elements. In general, the term “or” as used shall only be interpreted as indicating exclusive alternatives (i.e., “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

The use of “including,” “comprising,” “having,” “containing,” “involving,” and variations thereof, is meant to encompass the items listed thereafter and additional items.

Use of ordinal terms such as “first,” “second,” “third,” etc., in the claims to modify a claim element does not by itself connote any priority, precedence, or order of one claim element over another or the temporal order in which acts of a method are performed. Ordinal terms are used merely as labels to distinguish one claim element having a certain name from another element having a same name (but for use of the ordinal term), to distinguish the claim elements.

While this specification contains many specific implementation details, these should not be construed as limitations on the scope of what may be claimed, but rather as descriptions of features that may be specific to particular embodiments. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

The process parameters and sequence of the steps described and/or illustrated herein are given by way of example only and can be varied as desired. For example, while the steps illustrated and/or described herein are shown or discussed in a particular order, these steps do not necessarily need to be performed in the order illustrated or discussed. The various exemplary methods described and/or illustrated herein can also omit one or more of the steps described or illustrated herein or include additional steps in addition to those disclosed.

The preceding description has been provided to enable others skilled in the art to best utilize various aspects of the exemplary implementations disclosed herein. This exemplary description is not intended to be exhaustive or to be limited to any precise form disclosed. Many modifications and variations are possible without departing from the spirit and scope of the present disclosure. The implementations disclosed herein should be considered in all respects illustrative and not restrictive. Reference should be made to the appended claims and their equivalents in determining the scope of the present disclosure.

What is claimed is:

1. A device comprising:
an assembly including
a first die comprising a first integrated passive device (IPD),
at least one through-silicon via (TSV) extending through the first die from a first surface of the first die to a second surface of the first die, and
a second die comprising power delivery circuitry or a second IPD, wherein a surface of the second die is bonded to the first surface of the first die.

2. The device of claim 1, further comprising a substrate having a cavity formed therein, wherein the assembly is disposed in the cavity.

3. The device of claim 1, wherein the second die comprises the power delivery circuitry, and the assembly further comprises a third die comprising the second IPD, the third die being bonded to a second surface of the first die.

4. The device of claim 3, wherein the third die is fusion bonded to the second surface of the first die.

5. The device of claim 1, wherein the first IPD comprises a first deep trench capacitor, the second die comprises the second IPD, and the second IPD comprises a second deep trench capacitor.

6. The device of claim 3, wherein the first IPD comprises a first deep trench capacitor, the second IPD comprises a second deep trench capacitor, and the power delivery circuitry comprises an integrated voltage regulator.

7. The device of claim 1, wherein the first IPD comprises a deep trench capacitor, the second die comprises the power delivery circuitry, the power delivery circuitry comprises an integrated voltage regulator, the first surface of the first die is hybrid bonded to the second die, and the first die further includes a conductive layer formed on a second surface opposite the first surface.

8. The device of claim 2, wherein a thickness of the assembly matches a thickness of the substrate having the cavity formed therein.

9. The device of claim 1, wherein the first die or the second die includes a thermal carrier die.

10. A method comprising:
forming a cavity within a substrate of an integrated circuit,
placing a wafer-on-wafer assembly within the cavity of the substrate, wherein the wafer-on-wafer assembly includes a first die having a first integrated passive device (IPD) formed thereon and a second die having a second integrated passive device (IPD) formed thereon;
filing the cavity with a material including resin after placing the wafer-on-wafer assembly within the cavity; and
laminating a first surface and a second surface of the integrated circuit.

11. A multi-chip package comprising:
a substrate, wherein a cavity is formed within the substrate;
a wafer-on-wafer assembly disposed within the cavity of the substrate, wherein the wafer-on-wafer assembly includes a first die comprising a first integrated passive device (IPD) and a second die comprising power delivery circuitry or a second integrated passive device (IPD); and
an integrated circuit communicatively coupled to the wafer-on-wafer assembly via one or more interconnects.

12. The multi-chip package of claim 11, wherein the integrated circuit is a first integrated circuit, and wherein the substrate is a core substrate of a printed circuit board or a substrate of a second integrated circuit.

13. The multi-chip package of claim 12, wherein at least one of the one or more interconnects is routed through the substrate.

14. The multi-chip package of claim 13, wherein the first integrated circuit is disposed on the substrate.

15. The multi-chip package of claim 12, further comprising an interposer disposed over the substrate, wherein at least one of the one or more interconnects is routed through the interposer.

16. The multi-chip package of claim 15, wherein the first integrated circuit is disposed on the interposer.

17. The multi-chip package of claim 11, wherein the wafer-on-wafer assembly further includes at least one through-silicon via (TSV) extending through the first die from a first surface of the first die to a second surface of the first die.

18. The multi-chip package of claim 17, wherein a surface of the second die is bonded to the first surface of the first die.

19. The multi-chip package of claim 11, wherein the second die comprises the power delivery circuitry, and the wafer-on-wafer assembly further includes a third die comprising the second IPD.

20. The multi-chip package of claim 11, wherein a material including resin is disposed within the cavity.
